(19) United States
(12) Patent Application Publication
(10) Pub. No.: US 2025/0348626 A1
(43) Pub. Date: Nov. 13, 2025

(54) METHODS AND APPARATUS FOR SMOOTHED PARTICLE HYDRODYNAMICS ANALYSIS

(71) Applicant: The Boeing Company, Arlington, VA (US)

(72) Inventors: Jonathan Wayne Gabrys, Downingtown, PA (US); Richard R. Laverty, Philadelphia, PA (US); Megan E. Prucnal, Wallingford, PA (US)

(21) Appl. No.: 18/659,736

(22) Filed: May 9, 2024

(51) Int. Cl. G06F 30/13; G06F 30/25; G06F 30/28

(52) U.S. Cl. CPC G06F 30/13; G06F 30/25; G06F 30/28

(57) ABSTRACT

Methods and apparatus for smoothed particle hydrodynamics (SPH) analysis are disclosed. A disclosed example apparatus to generate a design of a structure, the apparatus includes machine readable instructions, and at least one processor circuit to be programmed by the machine readable instructions to generate a space with a corresponding constraint and a load, the space including SPH particles, identify ones of the SPH particles carrying a load above a threshold load, and adjust, based on the identification, the SPH particles within the space to generate the design of the structure.

### FIELD OF THE DISCLOSURE

This disclosure relates generally to computational modelling and, more particularly, to methods and apparatus for smoothed particle hydrodynamics analysis.

### BACKGROUND

Topology Optimization (TO) is a mathematical methodology that optimizes material layout within a given design space for a defined set of loads, boundary conditions and constraints with the goal of maximizing a performance of a system. The material distribution in each Eulerian (fixed mesh) element, or density, is variable. As a result, TO results typically appear organic, unlike traditional structural designs.

### SUMMARY

An example apparatus to generate a design of a structure, the apparatus includes machine readable instructions, and at least one processor circuit to be programmed by the machine readable instructions to generate a space with a corresponding constraint and a load, the space including smooth particle hydrodynamics (SPH) particles, identify ones of the SPH particles carrying a load above a threshold load, and adjust, based on the identification, the SPH particles within the space to generate the design of the structure.

An example non-transitory machine readable storage medium includes instructions to cause at least one processor circuit to at least generate a space with a corresponding constraint and a load, the space including smooth particle hydrodynamics (SPH) particles, identify ones of the SPH particles as load carrying to define a keep volume, at least one of (i) remove SPH particles from the space (ii) move ones of the SPH particles that are not identified as load carrying to the keep volume based on the identification or (iii) increase a number of SPH particles in the keep volume, and generate a design of a structure based on an arrangement of the SPH particles.

An example method includes generating, by executing instructions with at least one processor circuit, a space with a corresponding constraint and a load, the space including smooth particle hydrodynamics (SPH) particles, identifying, by executing instructions with one or more of the at least one processor circuit, ones of the SPH particles as load carrying to define a keep volume, moving, by executing instructions with one or more of the at least one processor circuit, ones of the SPH particles that are not identified as load carrying to the keep volume based on the identification, and generating, by executing instructions with one or more of the at least one processor circuit, a design of a structure based on an arrangement of the SPH particles.

### BRIEF DESCRIPTION OF THE DRAWINGS

FIG. 1 is an example system in accordance with teachings of this disclosure.

FIGS. 2A and 2B depict an example design generation methodology in accordance with teachings of this disclosure.

FIG. 3 is schematic overview of an example SPH analysis system to implement examples disclosed herein.

FIG. 4 is a flowchart representative of example machine readable instructions and/or example operations that may be executed, instantiated, and/or performed by example programmable circuitry to implement the SPH analysis system of FIG. 3.

FIG. 5 is a block diagram of an example processing platform including programmable circuitry structured to execute, instantiate, and/or perform the example machine readable instructions and/or perform the example operations of FIG. 4 to implement the SPH analysis system of FIG. 3.

FIG. 6 is a block diagram of an example implementation of the programmable circuitry of FIG. 5.

FIG. 7 is a block diagram of another example implementation of the programmable circuitry of FIG. 5.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Methods and apparatus for smoothed particle hydrodynamics (SPH) analysis are disclosed. For structural design of components and/or systems, known implementations utilize Topology Optimization (TO). Although this known technique is generally effective, many nodes/elements are necessitated to generate an accurate concept with an obvious distinction between elements of high density and low density. Depending on the model size, required computer runtimes may prevent generation of design concepts in a relatively quick manner due to the number of nodes/elements.

Examples disclosed herein can be utilized in a computationally efficient manner. Examples disclosed herein can enable quick generation of design geometry for given constraints as well as loading conditions. Examples disclosed herein can also effectively generate geometry and/or a part design that is light weight and/or space-saving, which can be particularly advantageous for aircraft applications, amongst other applications. Further, examples disclosed herein can generate relatively complex geometry that would be otherwise difficult to determine.

Examples disclosed herein utilize SPH, which is a computational method for simulating mechanics of continuum media, such as solid mechanics and fluid flows. Examples disclosed herein employ a meshfree Lagrangian method and the resolution of the method can be adjusted in a relatively easy manner with respect to variables, such as density, for example. In contrast to known implementations, examples disclosed herein do not necessitate a definition of nodes and elements as in a finite element analysis. Instead, only a collection of points or nodes are utilized to represent a given body. In a context of analysis utilizing SPH, these nodes are commonly referred to as particles or pseudo-particles.

Unlike the aforementioned TO where density is added inside an element volume that is required to support a predefined load, SPH methodology according to examples disclosed herein can retain SPH particles that are necessitated to support a predefined load. According to examples disclosed herein, multiple convergence steps can be performed. For each step, SPH particles designated and/or determined to support a load are identified, and an additional amount of particles proximate or at a boundary are determined to define a keep volume, for example. Accordingly, a subsequent step can increase (or reduce) a number of SPH Particles in the keep volume and run an additional computational step. According to examples disclosed herein, as additional steps are performed, a structural shape will emerge with increased fidelity.

Examples disclosed herein generate, define and/or determine a model having a space (e.g., a design space, a volume, a volumetric region, etc.) with a boundary condition and a load. The space includes (e.g., is filled with) SPH particles. According to examples disclosed herein, SPH particles carrying a load above a threshold load (e.g., a threshold load level) are identified. In turn, SPH particles not carrying a load above the threshold load are at least one of removed or moved/offset/displaced within the space. In some examples, the SPH particles are moved toward a keep volume during and/or between iterations. Additionally or alternatively, the SPH particles are consolidated into an area (e.g., a keep volume area). Examples disclosed herein can be repeated in a reiterative process to refine the aforementioned model such that SPH particles can be moved, changed in size, removed and/or redistributed.

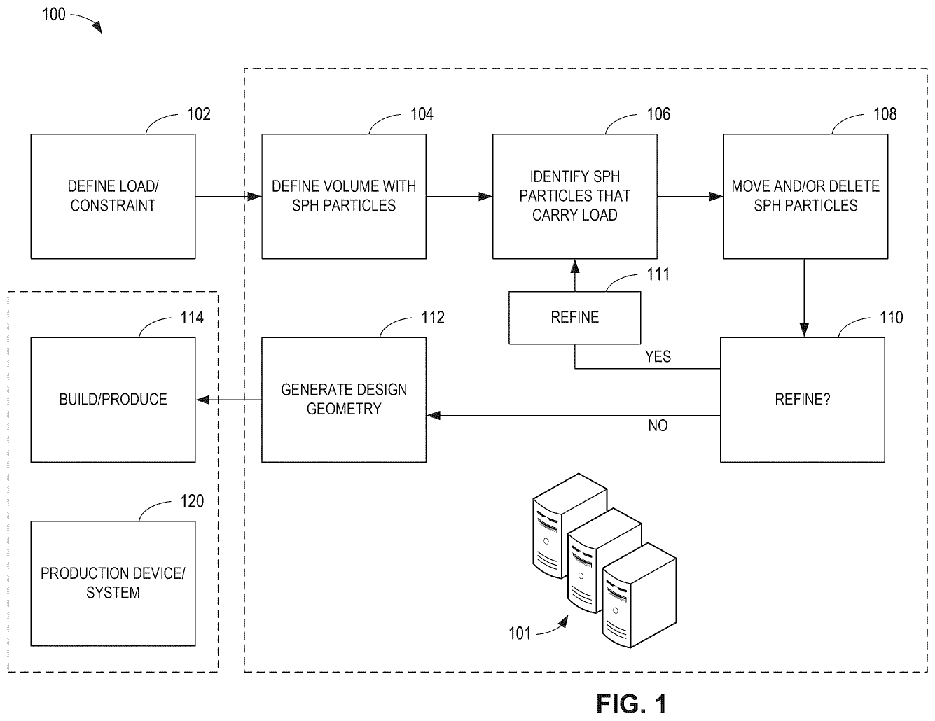

FIG. 1 is an example system 100 in accordance with teachings of this disclosure. In the illustrated example of FIG. 1, a computing system/device 101 is to perform a computational process to develop a design/geometry that utilizes a reduced amount of material/volume (e.g., for an aircraft application, for a vehicle application, etc.). At block 102, a load and constraint are defined with respect to a volume (e.g., a space, a design space). At block 104, SPH particles are defined in the volume. For example, the volume contains and/or is filled with the SPH particles and/or the SPH particles are sized to occupy (e.g., fill) the volume with a discrete number of the SPH particles. At block 106, it is determined and/or calculated which of the SPH particles are carrying a load. In this example, the SPH particles are identified based on being determined to carry a threshold load that exceeds a load threshold (e.g., a load threshold value). At block 108, the SPH particles that are determined to carry the load are moved and/or deleted. Additionally or alternatively, at block 110, it is determined whether the SPH particles carrying the load are to be refined. At block 111, the SPH particles are refined and/or adjusted. In some examples, the SPH particles are consolidated into a smaller targeted space (e.g., a keep area). At block 112, a design geometry (e.g., a model structure) is generated based on the remaining SPH particles. In some examples, at step 114, a structure is produced and/or built (e.g., via an additive production process, etc.) by a production device/system 120, which can be implemented as an additive production device or a 3D-printing device, for example.

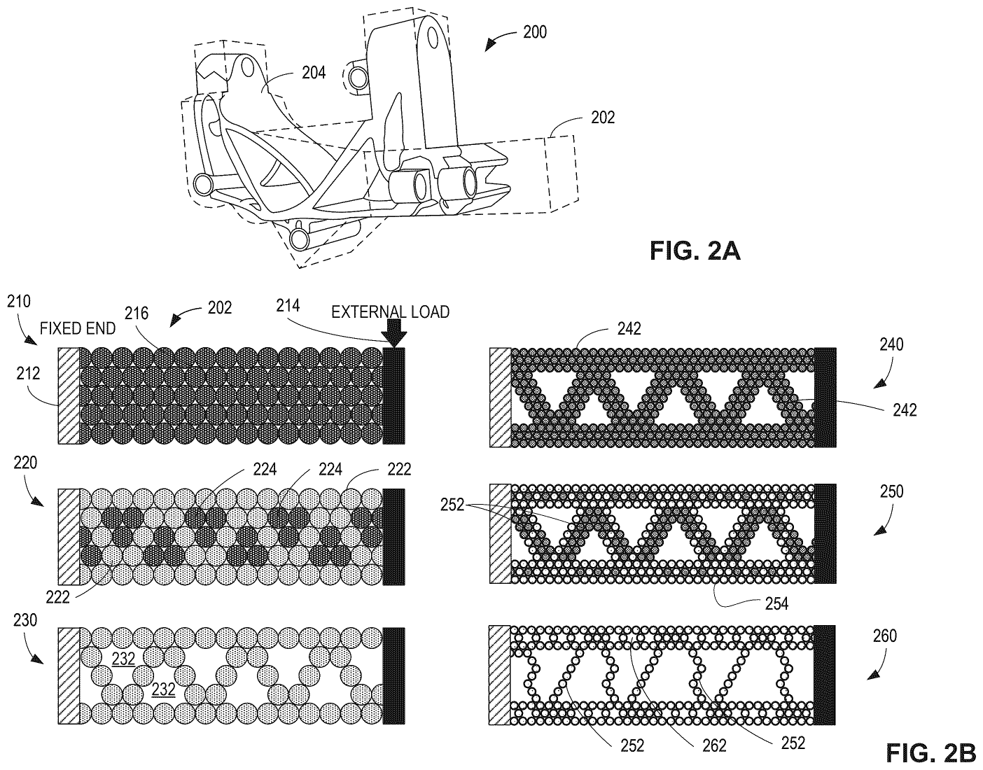

FIGS. 2A and 2B depict an example design generation methodology in accordance with teachings of this disclosure. Turning to FIG. 2A, an example design space 200 is shown. In the illustrated example of FIG. 2A, an example space/volume (e.g., a design space) 202 is shown with features/structures 204. According to some examples disclosed herein, the features/structures 204 can coincide with inputs, which may correspond to restraints, loading and/or boundary conditions. Accordingly, examples disclosed can account for the inputs to generate a design of a structure (e.g., a design structure) that achieves certain objectives, such as minimizing weight for example, which can be highly advantageous for aircraft applications, amongst other applications.

Turning to FIG. 2B, at step 210, a constraint 212, which is a fixed end in this example, is depicted with an external load 214. Further, the aforementioned space/volume 202 contains SPH particles 216 (e.g., is filled with the SPH particles 216). In some examples, the space/volume 202 is filled with the SPH particles 216 such that the complete (particles are contained with the space/volume 202. In some such examples, the SPH particles 216 are sized so that a multiple thereof can be placed across different dimensions/directions of the space/volume 202.

At step 220, particles 222 are determined to be load carrying. In contrast, particles 224 are determined not to be load carrying. The determination can be based on whether individual ones of the SPH particles 216 carry loads that exceed a load threshold.

At step 230, the particles 224 are moved and/or deleted, thereby resulting in voids 232. According to examples disclosed herein, areas away from the voids 232 define a keep volume. In turn, the keep volume and/or remaining SPH particles can define the shape/geometry of a part and/or design geometry to be generated/determined.

At step 240, the particles 222 shown in step 230 are refined to define refined particles 242. In some examples, the particles 224 of step 220 are consolidated into a smaller area/region (e.g., moved toward the particles 222) to define the particles 242. In some other examples, sizes of the particles 224 are adjusted (e.g., reduced in size, increased in size, etc.).

At step 250, load carrying particles 252 and non-load carrying particles 254 (of the particles 242 of step 240) are determined.

At step 260, the non-load carrying particles 254 shown in step 250 are removed, thereby defining pockets/voids 262. Alternatively, the non-load carrying particles 254 are moved toward the load carrying particles 252 (e.g., toward locations of the load carrying particles 252). According to examples disclosed herein the load carrying particles 252 define a keep volume which, in turn, is to define a shape of a structure with favorable characteristics.

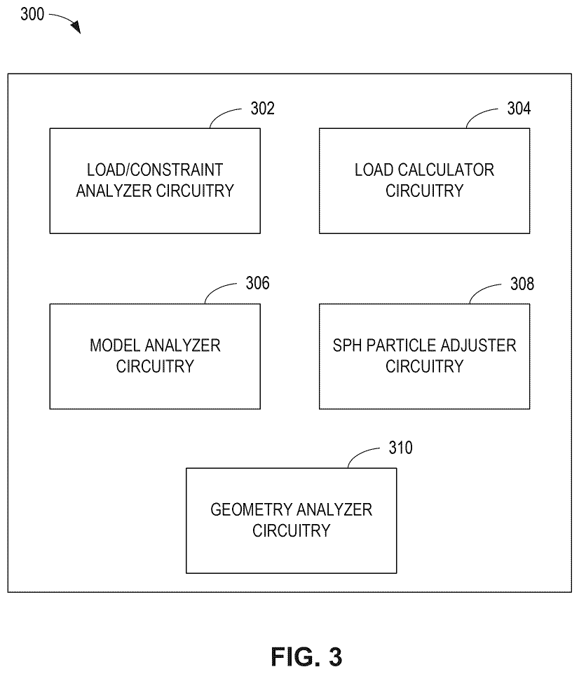

FIG. 3 is a block diagram of an example implementation of an SPH analysis system 300 to utilize an SPH model for generation of a design geometry. The SPH analysis system 300 of FIG. 3 may be instantiated (e.g., creating an instance of, bring into being for any length of time, materialize, implement, etc.) by programmable circuitry such as a Central Processor Unit (CPU) executing first instructions. Additionally or alternatively, the SPH analysis system 300 of FIG. 3 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 3 may, thus, be instantiated at the same or different times. Some or all of the circuitry of FIG. 3 may be instantiated, for example, in one or more threads executing concurrently on hardware and/or in series on hardware. Moreover, in some examples, some or all of the circuitry of FIG. 3 may be implemented by microprocessor circuitry executing instructions and/or FPGA circuitry performing operations to implement one or more virtual machines and/or containers.

The SPH analysis system 300 of the illustrated example includes example load/constraint analyzer circuitry 302, example load calculator circuitry 304, example model analyzer circuitry 306, example SPH particle adjuster circuitry 308, and example geometry analyzer circuitry 310. In some examples, the SPH analysis system 300 is communicatively coupled to an additive production machine, such as the example production device shown in FIG. 1.

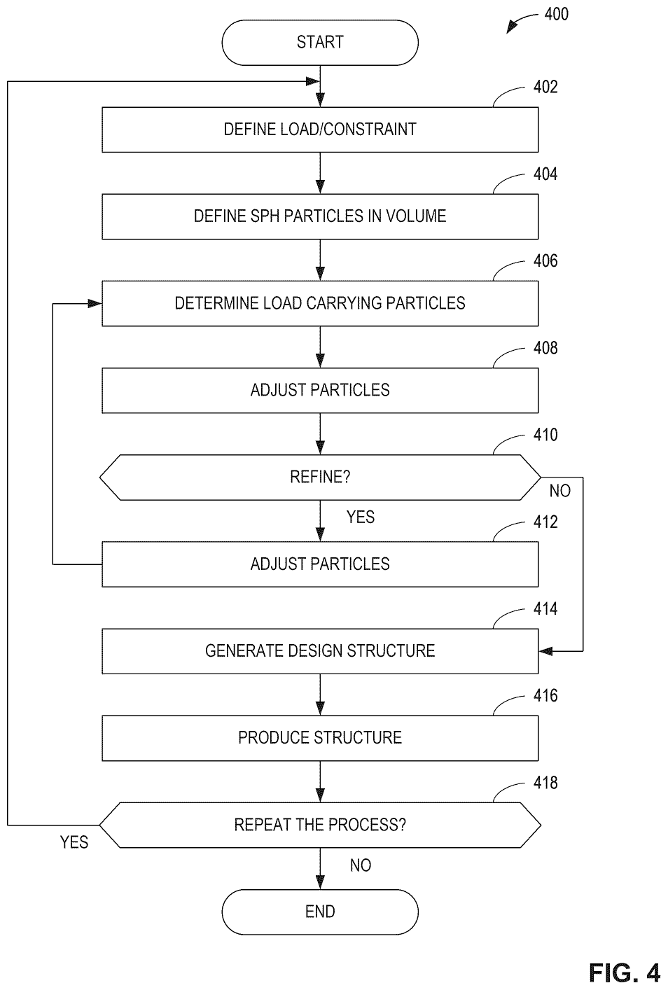

In the illustrated example of FIG. 3, the load/constraint analyzer circuitry 302 characterizes, defines and/or determines any loads or constraints defined with respect to a model (e.g., a representation, a load model, a structure model, etc.) corresponding to and/or including a design space which, in turn, includes and/or contains SPH particles distributed within. According to examples disclosed herein, the load/constraint analyzer circuitry 302 defines a constraint within the design space (e.g., a fixed constraint at a position, area and/or volume of the design space), as well as a load applied to at least one area or portion of the design space. In some examples, the load/constraint analyzer circuitry 302 is instantiated by programmable circuitry executing load/constraint analyzer instructions and/or configured to perform operations such as those represented by the flowchart of FIG. 4.

The example load calculator circuitry 304 is implemented to perform load calculations utilizing the SPH particles. In this example, the load calculator circuitry 304 determines loads of the SPH particles based on the constraint and the load. According to some examples disclosed herein, the load calculator circuitry 304 determines loads carried by ones of the SPH particles. In turn, the loads can be compared to a load threshold for subsequent refinement of the model. According to some examples disclosed herein, portions and/or regions of the design space determined to be carrying a load above the load threshold define a keep volume. In some examples, the load calculator circuitry determines and/or identifies the keep volume. In some examples, the load calculator circuitry 304 is instantiated by programmable circuitry executing load calculator instructions and/or configured to perform operations such as those represented by the flowchart of FIG. 4.

In some examples, the model analyzer circuitry 306 is implemented to determine an accuracy of the model, whether the model has converged (e.g., converged to a convergence criteria) and/or whether further refinement of the model and/or the SPH particles is to be performed. In some examples, the model analyzer circuitry 306 is instantiated by programmable circuitry executing model analyzer instructions and/or configured to perform operations such as those represented by the flowchart of FIG. 4.

The example SPH particle adjuster 308 is implemented to move, displace, group remove, refine the SPH particles (e.g., based on iterative steps). According to some examples disclosed herein, SPH particles determined to be carrying a load that is less than a load threshold are removed from the design space and/or the aforementioned keep volume or moved toward a portion/region of the design space determined to be carrying a load above the load threshold. In some examples, SPH particles located at a boundary of the design space and/or constraints are retained (e.g., without carrying a load above the load threshold). In some examples, a number of the SPH particles in the keep volume is increased. Additionally or alternatively, a size of at least one of the SPH particles is adjusted (e.g., the size is decreased, the size is increased, etc.). According to some examples disclosed herein, between iterations, SPH particle sizes are displaced and SPH particles that are not carrying a load above the load threshold are removed and/or moved within the design space (e.g., consolidated to portions of the design space designated to be carrying a load above the load threshold). In some examples, the SPH particle adjuster circuitry 308 is instantiated by programmable circuitry executing SPH particle adjuster instructions and/or configured to perform operations such as those represented by the flowchart of FIG. 4.

According to some examples disclosed herein, the geometry analyzer circuitry 310 is utilized to determine and/or generate a geometry (e.g., a design structure) of an object based on an arrangement of the SPH particles in the aforementioned design space. In the illustrated example of FIG. 3, the geometry is generated based on remaining ones of the SPH particles. In other words, retained SPH particles are utilized to define and/or create geometry. In some examples, a 3D model or other representation is generated based on the SPH particles remaining in the design space. The 3D model can be utilized for an additive manufacturing/build process, for example. In some examples, the geometry analyzer circuitry 310 is instantiated by programmable circuitry executing geometry analyzer instructions and/or configured to perform operations such as those represented by the flowchart of FIG. 4.

While an example manner of implementing the SPH analysis system 300 of FIG. 3 is illustrated in FIG. 3, one or more of the elements, processes, and/or devices illustrated in FIG. 3 may be combined, divided, re-arranged, omitted, eliminated, and/or implemented in any other way. Further, the example load/constraint analyzer circuitry 302, the example load calculator circuitry 304, the example model analyzer circuitry 306, the example SPH particle adjuster circuitry 308, the example geometry analyzer circuitry 310, and/or, more generally, the example SPH analysis system 300 of FIG. 3, may be implemented by hardware alone or by hardware in combination with software and/or firmware. Thus, for example, any of the example load/constraint analyzer circuitry 302, the example load calculator circuitry 304, the example model analyzer circuitry 306, the example SPH particle adjuster circuitry 308, the example geometry analyzer circuitry 310, and/or, more generally, the example SPH analysis system 300, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example SPH analysis system 300 of FIG. 3 may include one or more elements, processes, and/or devices in addition to, or instead of, those illustrated in FIG. 3, and/or may include more than one of any or all of the illustrated elements, processes and devices.

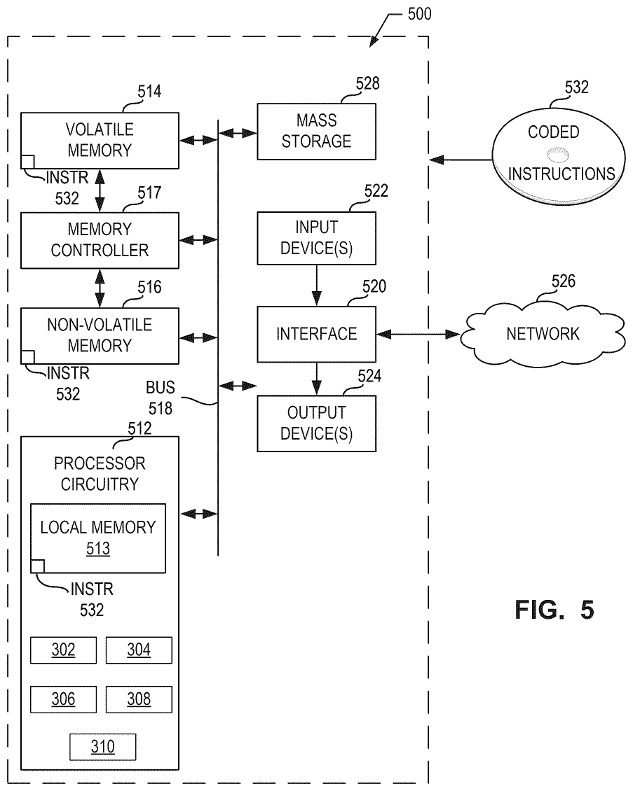

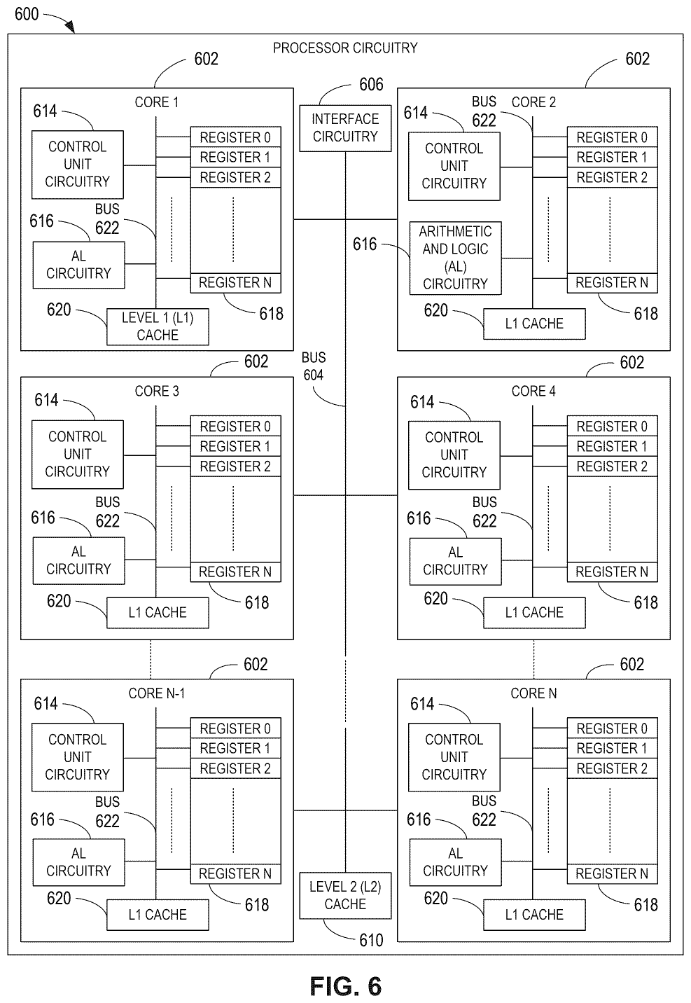

A flowchart representative of example machine readable instructions, which may be executed by programmable circuitry to implement and/or instantiate the SPH analysis system 300 of FIG. 3 and/or representative of example operations which may be performed by programmable circuitry to implement and/or instantiate the SPH analysis system 300 of FIG. 3, are shown in FIG. 4. The machine readable instructions may be one or more executable programs or portion(s) of one or more executable programs for execution by programmable circuitry such as the programmable circuitry 512 shown in the example processor platform 500 discussed below in connection with FIG. 5 and/or may be one or more function(s) or portion(s) of functions to be performed by the example programmable circuitry (e.g., an FPGA) discussed below in connection with FIGS. 6 and/or 7. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart illustrated in FIG. 4, many other methods of implementing the example SPH analysis system 300 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 4 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

FIG. 4 is a flowchart representative of example machine readable instructions and/or example operations 400 that may be executed, instantiated, and/or performed by programmable circuitry to generate a geometry and/or structure that is relatively lightweight and/or does not include a significant volume. The example machine-readable instructions and/or the example operations 400 of FIG. 4 begin at block 402, at which the example load/constraint analyzer circuitry 302 defines and/or determines a load and/or a constraint with respect to a design space.

At block 404, in this example, SPH particles are defined by the example load/constraint analyzer circuitry 302 to be within a volume of the design space. In this example, the load/constraint analyzer circuitry 302 arranges the SPH particles to be evenly spaced across the volume. In some examples, the SPH particles are sized based on dimensions of the volume (e.g., the SPH particles are sized to fit within the volume (e.g., as undivided SPH particles).

At block 406, the example load calculator circuitry 304 calculates loads of the SPH particles to determine and/or identify load carrying SPH particles. In the illustrated example of FIG. 4, the example load calculator circuitry 304 calculates loads for each of the SPH particles and, based on the loads, the example load calculator circuitry 304 determines which of the SPH particles are load carrying. In this example, SPH particles are determined to be load carrying if they exhibit a load that exceeds a load threshold. In some particular examples, loads at or relatively close to zero are determined not to be load carrying.

At block 408, the example SPH particle adjuster 308 adjusts the model and/or the SPH particles. In the illustrated example of FIG. 4, positions/locations in the design space are adjusted. In some examples, sizes and/or density of the SPH particles are adjusted. Additionally or alternatively, SPH particles below the load threshold (e.g., determined not to be load carrying) are removed from the design space.

At block 410, the example model analyzer circuitry 306 determines whether to refine the model and/or the SPH particles. If the model and/or the SPH particles are to be refined (block 410), control of the process proceeds to block 412. Otherwise, the process proceeds to block 414.

At block 412, the example SPH particle adjuster 308 adjusts the model and/or the SPH particles. In the illustrated example of FIG. 4, the positions/locations of the SPH particles in the design space are adjusted. Additionally or alternatively, SPH particles below the load threshold (e.g., determined not to be load carrying) are removed from the design space.

At block 414, the example geometry analyzer circuitry 310 generates and/or determines a design structure. In this example, a 3D model of geometry corresponding to the remaining SPH particles is generated based on the SPH particles arranged in the design space. In particular, the 3D model of the geometry can be generated based on how the SPH particles have been moved, resized and/or omitted.

At block 416, in some examples, the geometry analyzer circuitry 310 causes a production device to produce a structure, part and/or component (e.g., based on the 3D model).

At block 418, it is determined whether to repeat the process. If the process is to be repeated (block 418), control of the process returns to block 402. Otherwise, the process ends. This determination may be based on whether additional structures are to be designed/determined and/or additional parts/components are to be analyzed, generated and/or produced.

FIG. 5 is a block diagram of an example programmable circuitry platform 500 structured to execute and/or instantiate the example machine-readable instructions and/or the example operations of FIG. 4 to implement the SPH analysis system 300 of FIG. 3. The programmable circuitry platform 500 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 500 of the illustrated example includes programmable circuitry 512. The programmable circuitry 512 of the illustrated example is hardware. For example, the programmable circuitry 512 can be implemented by one or more integrated circuits, logic circuits, FPGAs, microprocessors, CPUs, GPUs, DSPs, and/or microcontrollers from any desired family or manufacturer. The programmable circuitry 512 may be implemented by one or more semiconductor based (e.g., silicon based) devices. In this example, the programmable circuitry 512 implements the example load/constraint analyzer circuitry 302, the example load calculator circuitry 304, the example model analyzer circuitry 306, the example SPH particle adjuster circuitry 308, and the example geometry analyzer circuitry 310.

The programmable circuitry 512 of the illustrated example includes a local memory 513 (e.g., a cache, registers, etc.). The programmable circuitry 512 of the illustrated example is in communication with main memory 514, 516, which includes a volatile memory 514 and a non-volatile memory 516, by a bus 518. The volatile memory 514 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 516 may be implemented by flash memory and/or any other desired type of memory device. Access to the main memory 514, 516 of the illustrated example is controlled by a memory controller 517. In some examples, the memory controller 517 may be implemented by one or more integrated circuits, logic circuits, microcontrollers from any desired family or manufacturer, or any other type of circuitry to manage the flow of data going to and from the main memory 514, 516.

The programmable circuitry platform 500 of the illustrated example also includes interface circuitry 520. The interface circuitry 520 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 522 are connected to the interface circuitry 520. The input device(s) 522 permit(s) a user (e.g., a human user, a machine user, etc.) to enter data and/or commands into the programmable circuitry 512. The input device(s) 522 can be implemented by, for example, an audio sensor, a microphone, a camera (still or video), a keyboard, a button, a mouse, a touchscreen, a trackpad, a trackball, an isopoint device, and/or a voice recognition system.

One or more output devices 524 are also connected to the interface circuitry 520 of the illustrated example. The output device(s) 524 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 520 of the illustrated example, thus, typically includes a graphics driver card, a graphics driver chip, and/or graphics processor circuitry such as a GPU.

The interface circuitry 520 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 526. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 500 of the illustrated example also includes one or more mass storage discs or devices 528 to store firmware, software, and/or data. Examples of such mass storage discs or devices 528 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 532, which may be implemented by the machine readable instructions of FIG. 4, may be stored in the mass storage device 528, in the volatile memory 514, in the non-volatile memory 516, and/or on at least one non-transitory computer readable storage medium such as a CD or DVD which may be removable.

FIG. 6 is a block diagram of an example implementation of the programmable circuitry 512 of FIG. 5. In this example, the programmable circuitry 512 of FIG. 5 is implemented by a microprocessor 600. For example, the microprocessor 600 may be a general-purpose microprocessor (e.g., general-purpose microprocessor circuitry). The microprocessor 600 executes some or all of the machine-readable instructions of the flowchart of FIG. 4 to effectively instantiate the circuitry of FIG. 3 as logic circuits to perform operations corresponding to those machine readable instructions. In some such examples, the circuitry of FIG. 3 is instantiated by the hardware circuits of the microprocessor 600 in combination with the machine-readable instructions. For example, the microprocessor 600 may be implemented by multi-core hardware circuitry such as a CPU, a DSP, a GPU, an XPU, etc. Although it may include any number of example cores 602 (e.g., 1 core), the microprocessor 600 of this example is a multi-core semiconductor device including N cores. The cores 602 of the microprocessor 600 may operate independently or may cooperate to execute machine readable instructions. For example, machine code corresponding to a firmware program, an embedded software program, or a software program may be executed by one of the cores 602 or may be executed by multiple ones of the cores 602 at the same or different times. In some examples, the machine code corresponding to the firmware program, the embedded software program, or the software program is split into threads and executed in parallel by two or more of the cores 602. The software program may correspond to a portion or all of the machine readable instructions and/or operations represented by the flowchart of FIG. 4.

The cores 602 may communicate by a first example bus 604. In some examples, the first bus 604 may be implemented by a communication bus to effectuate communication associated with one(s) of the cores 602. For example, the first bus 604 may be implemented by at least one of an Inter-Integrated Circuit (I2C) bus, a Serial Peripheral Interface (SPI) bus, a PCI bus, or a PCIe bus. Additionally or alternatively, the first bus 604 may be implemented by any other type of computing or electrical bus. The cores 602 may obtain data, instructions, and/or signals from one or more external devices by example interface circuitry 606. The cores 602 may output data, instructions, and/or signals to the one or more external devices by the interface circuitry 606. Although the cores 602 of this example include example local memory 620 (e.g., Level 1 (L1) cache that may be split into an L1 data cache and an L1 instruction cache), the microprocessor 600 also includes example shared memory 610 that may be shared by the cores (e.g., Level 2 (L2 cache)) for high-speed access to data and/or instructions. Data and/or instructions may be transferred (e.g., shared) by writing to and/or reading from the shared memory 610. The local memory 620 of each of the cores 602 and the shared memory 610 may be part of a hierarchy of storage devices including multiple levels of cache memory and the main memory (e.g., the main memory 514, 516 of FIG. 5). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 602 may be referred to as a CPU, DSP, GPU, etc., or any other type of hardware circuitry. Each core 602 includes control unit circuitry 614, arithmetic and logic (AL) circuitry (sometimes referred to as an ALU) 616, a plurality of registers 618, the local memory 620, and a second example bus 622. Other structures may be present. For example, each core 602 may include vector unit circuitry, single instruction multiple data (SIMD) unit circuitry, load/store unit (LSU) circuitry, branch/jump unit circuitry, floating-point unit (FPU) circuitry, etc. The control unit circuitry 614 includes semiconductor-based circuits structured to control (e.g., coordinate) data movement within the corresponding core 602. The AL circuitry 616 includes semiconductor-based circuits structured to perform one or more mathematic and/or logic operations on the data within the corresponding core 602. The AL circuitry 616 of some examples performs integer based operations. In other examples, the AL circuitry 616 also performs floating-point operations. In yet other examples, the AL circuitry 616 may include first AL circuitry that performs integer-based operations and second AL circuitry that performs floating-point operations. In some examples, the AL circuitry 616 may be referred to as an Arithmetic Logic Unit (ALU).

The registers 618 are semiconductor-based structures to store data and/or instructions such as results of one or more of the operations performed by the AL circuitry 616 of the corresponding core 602. For example, the registers 618 may include vector register(s), SIMD register(s), general-purpose register(s), flag register(s), segment register(s), machine-specific register(s), instruction pointer register(s), control register(s), debug register(s), memory management register(s), machine check register(s), etc. The registers 618 may be arranged in a bank as shown in FIG. 6. Alternatively, the registers 618 may be organized in any other arrangement, format, or structure, such as by being distributed throughout the core 602 to shorten access time. The second bus 622 may be implemented by at least one of an I2C bus, a SPI bus, a PCI bus, or a PCIe bus.

Each core 602 and/or, more generally, the microprocessor 600 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 600 is a semiconductor device fabricated to include many transistors interconnected to implement the structures described above in one or more integrated circuits (ICs) contained in one or more packages.

The microprocessor 600 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 600, in the same chip package as the microprocessor 600 and/or in one or more separate packages from the microprocessor 600.

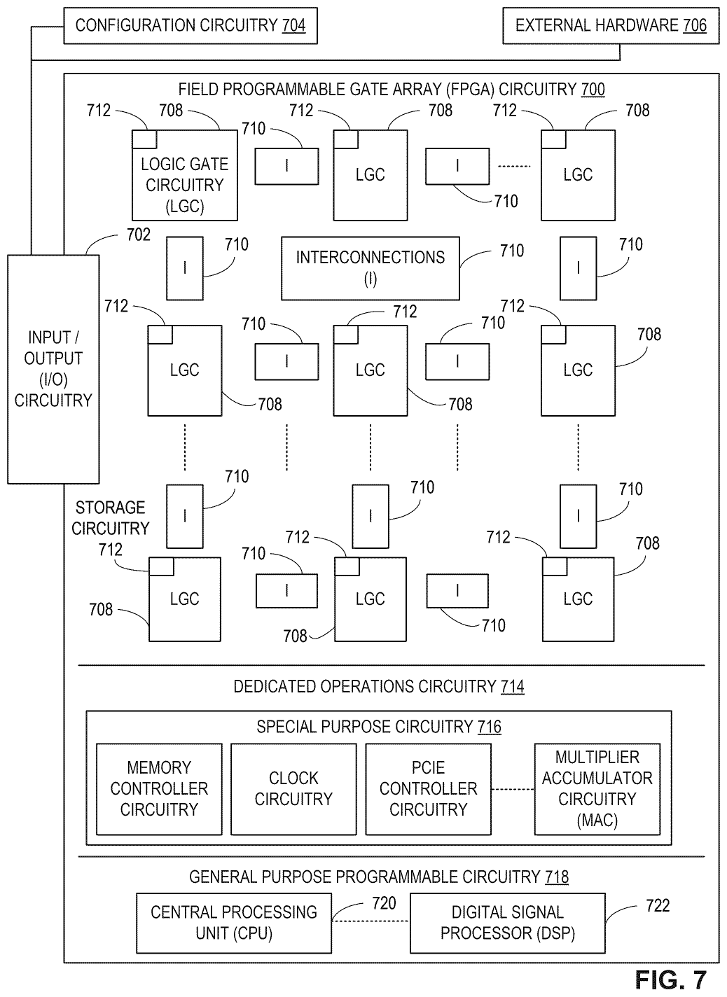

FIG. 7 is a block diagram of another example implementation of the programmable circuitry 512 of FIG. 5. In this example, the programmable circuitry 512 is implemented by FPGA circuitry 700. For example, the FPGA circuitry 700 may be implemented by an FPGA. The FPGA circuitry 700 can be used, for example, to perform operations that could otherwise be performed by the example microprocessor 600 of FIG. 6 executing corresponding machine readable instructions. However, once configured, the FPGA circuitry 700 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 600 of FIG. 6 described above (which is a general purpose device that may be programmed to execute some or all of the machine readable instructions represented by the flowchart of FIG. 4 but whose interconnections and logic circuitry are fixed once fabricated), the FPGA circuitry 700 of the example of FIG. 7 includes interconnections and logic circuitry that may be configured, structured, programmed, and/or interconnected in different ways after fabrication to instantiate, for example, some or all of the operations/functions corresponding to the machine readable instructions represented by the flowchart of FIG. 4. In particular, the FPGA circuitry 700 may be thought of as an array of logic gates, interconnections, and switches. The switches can be programmed to change how the logic gates are interconnected by the interconnections, effectively forming one or more dedicated logic circuits (unless and until the FPGA circuitry 700 is reprogrammed). The configured logic circuits enable the logic gates to cooperate in different ways to perform different operations on data received by input circuitry. Those operations may correspond to some or all of the instructions (e.g., the software and/or firmware) represented by the flowchart of FIG. 4. As such, the FPGA circuitry 700 may be configured and/or structured to effectively instantiate some or all of the operations/functions corresponding to the machine readable instructions of the flowchart of FIG. 4 as dedicated logic circuits to perform the operations/functions corresponding to those software instructions in a dedicated manner analogous to an ASIC. Therefore, the FPGA circuitry 700 may perform the operations/functions corresponding to the some or all of the machine readable instructions of FIG. 4 faster than the general-purpose microprocessor can execute the same.

In the example of FIG. 7, the FPGA circuitry 700 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 700 of FIG. 7 may access and/or load the binary file to cause the FPGA circuitry 700 of FIG. 7 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 700 of FIG. 7 to cause configuration and/or structuring of the FPGA circuitry 700 of FIG. 7, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 700 of FIG. 7 may access and/or load the binary file to cause the FPGA circuitry 700 of FIG. 7 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 700 of FIG. 7 to cause configuration and/or structuring of the FPGA circuitry 700 of FIG. 7, or portion(s) thereof.

The FPGA circuitry 700 of FIG. 7, includes example input/output (I/O) circuitry 702 to obtain and/or output data to/from example configuration circuitry 704 and/or external hardware 706. For example, the configuration circuitry 704 may be implemented by interface circuitry that may obtain a binary file, which may be implemented by a bit stream, data, and/or machine-readable instructions, to configure the FPGA circuitry 700, or portion(s) thereof. In some such examples, the configuration circuitry 704 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 706 may be implemented by external hardware circuitry. For example, the external hardware 706 may be implemented by the microprocessor 600 of FIG. 6.

The FPGA circuitry 700 also includes an array of example logic gate circuitry 708, a plurality of example configurable interconnections 710, and example storage circuitry 712. The logic gate circuitry 708 and the configurable interconnections 710 are configurable to instantiate one or more operations/functions that may correspond to at least some of the machine readable instructions of FIG. 4 and/or other desired operations. The logic gate circuitry 708 shown in FIG. 7 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 708 to enable configuration of the electrical structures and/or the logic gates to form circuits to perform desired operations/functions. The logic gate circuitry 708 may include other electrical structures such as look-up tables (LUTs), registers (e.g., flip-flops or latches), multiplexers, etc.

The configurable interconnections 710 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 708 to program desired logic circuits.

The storage circuitry 712 of the illustrated example is structured to store result(s) of the one or more of the operations performed by corresponding logic gates. The storage circuitry 712 may be implemented by registers or the like. In the illustrated example, the storage circuitry 712 is distributed amongst the logic gate circuitry 708 to facilitate access and increase execution speed.

The example FPGA circuitry 700 of FIG. 7 also includes example dedicated operations circuitry 714. In this example, the dedicated operations circuitry 714 includes special purpose circuitry 716 that may be invoked to implement commonly used functions to avoid the need to program those functions in the field. Examples of such special purpose circuitry 716 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 700 may also include example general purpose programmable circuitry 718 such as an example CPU 720 and/or an example DSP 722. Other general purpose programmable circuitry 718 may additionally or alternatively be present such as a GPU, an XPU, etc., that can be programmed to perform other operations.

Although FIGS. 6 and 7 illustrate two example implementations of the programmable circuitry 512 of FIG. 5, many other approaches are contemplated. For example, FPGA circuitry may include an on-board CPU, such as one or more of the example CPU 720 of FIG. 6. Therefore, the programmable circuitry 512 of FIG. 5 may additionally be implemented by combining at least the example microprocessor 600 of FIG. 6 and the example FPGA circuitry 700 of FIG. 7. In some such hybrid examples, one or more cores 602 of FIG. 6 may execute a first portion of the machine readable instructions represented by the flowchart of FIG. 4 to perform first operation(s)/function(s), the FPGA circuitry 700 of FIG. 7 may be configured and/or structured to perform second operation(s)/function(s) corresponding to a second portion of the machine readable instructions represented by the flowchart of FIG. 4, and/or an ASIC may be configured and/or structured to perform third operation(s)/function(s) corresponding to a third portion of the machine readable instructions represented by the flowchart of FIG. 4.

It should be understood that some or all of the circuitry of FIG. 3 may, thus, be instantiated at the same or different times. For example, same and/or different portion(s) of the microprocessor 600 of FIG. 6 may be programmed to execute portion(s) of machine-readable instructions at the same and/or different times. In some examples, same and/or different portion(s) of the FPGA circuitry 700 of FIG. 7 may be configured and/or structured to perform operations/functions corresponding to portion(s) of machine-readable instructions at the same and/or different times.

In some examples, some or all of the circuitry of FIG. 3 may be instantiated, for example, in one or more threads executing concurrently and/or in series. For example, the microprocessor 600 of FIG. 6 may execute machine readable instructions in one or more threads executing concurrently and/or in series. In some examples, the FPGA circuitry 700 of FIG. 7 may be configured and/or structured to carry out operations/functions concurrently and/or in series. Moreover, in some examples, some or all of the circuitry of FIG. 3 may be implemented within one or more virtual machines and/or containers executing on the microprocessor 600 of FIG. 6.

In some examples, the programmable circuitry 512 of FIG. 5 may be in one or more packages. For example, the microprocessor 600 of FIG. 6 and/or the FPGA circuitry 700 of FIG. 7 may be in one or more packages. In some examples, an XPU may be implemented by the programmable circuitry 512 of FIG. 5, which may be in one or more packages. For example, the XPU may include a CPU (e.g., the microprocessor 600 of FIG. 6, the CPU 720 of FIG. 7, etc.) in one package, a DSP (e.g., the DSP 722 of FIG. 7) in another package, a GPU in yet another package, and an FPGA (e.g., the FPGA circuitry 700 of FIG. 7) in still yet another package.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein, integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

Example methods, apparatus, systems, and articles of manufacture to enable efficient and relatively quick structure analysis are disclosed herein. Further examples and combinations thereof include the following:

Example 1 includes an apparatus to generate a design of a structure, the apparatus comprising machine readable instructions, and at least one processor circuit to be programmed by the machine readable instructions to generate a space with a corresponding constraint and a load, the space including smooth particle hydrodynamics (SPH) particles, identify ones of the SPH particles carrying a load above a threshold load, and adjust, based on the identification, the SPH particles within the space to generate the design of the structure.

Example 2 includes the apparatus as defined in example 1, wherein one or more of the at least one processor circuit is to consolidate the SPH particles into a smaller targeted space based on the identification of the SPH particles carrying the load above the threshold load.

Example 3 includes the apparatus as defined in example 2, wherein one or more of the at least one processor circuit is to determine a keep volume corresponding to the smaller targeted space.

Example 4 includes the apparatus as defined in example 1, wherein one or more of the at least one processor circuit is to move ones of the SPH particles not carrying a load above the threshold load toward a keep volume that is based on the identification.

Example 5 includes the apparatus as defined in example 1, wherein one or more of the at least one processor circuit is to determine a keep volume based on the identification of the SPH particles carrying a load above the threshold load, and wherein ones of the SPH particles that are not positioned in the keep volume are moved to the keep volume or removed.

Example 6 includes the apparatus as defined in example 1, wherein one or more of the at least one processor circuit is to determine a keep volume based on the identification, and wherein a number of SPH particles in the keep volume is increased.

Example 7 includes the apparatus as defined in example 1, wherein one or more of the at least one processor circuit is to retain ones of the SPH particles that do not carry a load above the threshold load positioned at or proximate a boundary.

Example 8 includes the apparatus as defined in example 1, wherein the generated design of the structure is based on remaining ones of the SPH particles.

Example 9 includes a non-transitory machine readable storage medium comprising instructions to cause at least one processor circuit to at least generate a space with a corresponding constraint and a load, the space including smooth particle hydrodynamics (SPH) particles, identify ones of the SPH particles as load carrying to define a keep volume, at least one of (i) remove SPH particles from the space (ii) move ones of the SPH particles that are not identified as load carrying to the keep volume based on the identification or (iii) increase a number of SPH particles in the keep volume, and generate a design of a structure based on an arrangement of the SPH particles.

Example 10 includes the non-transitory machine readable storage medium as defined in example 9, wherein the instructions cause one or more of the at least one processor circuit to determine the keep volume based on the identification, and wherein a number of SPH particles in the keep volume is increased.

Example 11 includes the non-transitory machine readable storage medium as defined in example 10, wherein the instructions cause one or more of the at least one processor circuit to identify ones of the refined SPH particles carrying a load, and remove or move ones of the refined SPH particles based on the identified ones of the refined SPH carrying the load.

Example 12 includes the non-transitory machine readable storage medium as defined in example 9, wherein the instructions cause one or more of the at least one processor circuit to move the SPH particles not identified as load carrying toward SPH particles identified to be load carrying.

Example 13 includes the non-transitory machine readable storage medium as defined in example 9, wherein one or more of the at least one processor circuit to cause an additive production device to produce the design of the structure.

Example 14 includes the non-transitory machine readable storage medium as defined in example 9, wherein the instructions cause one or more of the at least one processor circuit to retain SPH particles at or proximate at least one of a boundary or a constraint that are not identified as load carrying.

Example 15 includes a method comprising generating, by executing instructions with at least one processor circuit, a space with a corresponding constraint and a load, the space including smooth particle hydrodynamics (SPH) particles, identifying, by executing instructions with one or more of the at least one processor circuit, ones of the SPH particles as load carrying to define a keep volume, moving, by executing instructions with one or more of the at least one processor circuit, ones of the SPH particles that are not identified as load carrying to the keep volume based on the identification, and generating, by executing instructions with one or more of the at least one processor circuit, a design of a structure based on an arrangement of the SPH particles.

Example 16 includes the method as defined in example 15, further including increasing a number of the SPH particles in the keep volume.

Example 17 includes the method as defined in example 15, wherein ones of the SPH particles not identified as load carrying are moved toward SPH particles identified to be load carrying.

Example 18 includes the method as defined in example 17, wherein the part is produced based on the keep volume.

Example 19 includes the method as defined in example 15, further including producing, via an additive production device, a part based on the design of the structure.

Example 20 includes the method as defined in example 15, further including retaining, by executing instructions with one or more of the at least one processor circuit, ones of the SPH particles that are not identified as load carrying and positioned at or proximate at least one of a boundary or a constraint.

From the foregoing, it will be appreciated that example systems, apparatus, articles of manufacture, and methods have been disclosed that enable relatively quick and effective determination of structural designs. Examples disclosed herein can save computational resources, as well as analysis time. Disclosed systems, apparatus, articles of manufacture, and methods improve the efficiency of using a computing device by improving a computational efficiency of part design simulations and the typical trial and error experienced therewith. Examples disclosed herein can reduce and/or eliminate an amount of computation, thereby significantly saving computational resources. Disclosed systems, apparatus, articles of manufacture, and methods are accordingly directed to one or more improvement(s) in the operation of a machine such as a computer or other electronic and/or mechanical device.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus to generate a design of a structure, the apparatus comprising:
machine readable instructions; and
at least one processor circuit to be programmed by the machine readable instructions to:
generate a space with a corresponding constraint and a load, the space including smooth particle hydrodynamics (SPH) particles;
identify ones of the SPH particles carrying a load above a threshold load; and
adjust, based on the identification, the SPH particles within the space to generate the design of the structure.

2. The apparatus as defined in claim 1, wherein one or more of the at least one processor circuit is to consolidate the SPH particles into a smaller targeted space based on the identification of the SPH particles carrying the load above the threshold load.

3. The apparatus as defined in claim 2, wherein one or more of the at least one processor circuit is to determine a keep volume corresponding to the smaller targeted space.

4. The apparatus as defined in claim 1, wherein one or more of the at least one processor circuit is to move ones of the SPH particles not carrying a load above the threshold load toward a keep volume that is based on the identification.

5. The apparatus as defined in claim 1, wherein one or more of the at least one processor circuit is to determine a keep volume based on the identification of the SPH particles carrying a load above the threshold load, and wherein ones of the SPH particles that are not positioned in the keep volume are moved to the keep volume or removed.

6. The apparatus as defined in claim 1, wherein one or more of the at least one processor circuit is to determine a keep volume based on the identification of the SPH particles carrying the load above the threshold load, and wherein a number of SPH particles in the keep volume is increased.

7. The apparatus as defined in claim 1, wherein one or more of the at least one processor circuit is to retain ones of the SPH particles that do not carry a load above the threshold load positioned at or proximate a boundary.

8. The apparatus as defined in claim 1, wherein the generated design of the structure is based on remaining ones of the SPH particles.

9. A non-transitory machine readable storage medium comprising instructions to cause at least one processor circuit to at least:
generate a space with a corresponding constraint and a load, the space including smooth particle hydrodynamics (SPH) particles;
identify ones of the SPH particles as load carrying to define a keep volume;
at least one of (i) remove SPH particles from the space (ii) move ones of the SPH particles that are not identified as load carrying to the keep volume based on the identification or (iii) increase a number of SPH particles in the keep volume; and
generate a design of a structure based on an arrangement of the SPH particles.

10. The non-transitory machine readable storage medium as defined in claim 9, wherein the instructions cause one or more of the at least one processor circuit to determine the keep volume based on the identification, and wherein a number of SPH particles in the keep volume is increased.

11. The non-transitory machine readable storage medium as defined in claim 10, wherein the instructions cause one or more of the at least one processor circuit to:
identify ones of the refined SPH particles carrying a load; and
remove or move ones of the refined SPH particles based on the identified ones of the refined SPH carrying the load.

12. The non-transitory machine readable storage medium as defined in claim 9, wherein the instructions cause one or more of the at least one processor circuit to move the SPH particles not identified as load carrying toward SPH particles identified to be load carrying.

13. The non-transitory machine readable storage medium as defined in claim 9, wherein one or more of the at least one processor circuit to cause an additive production device to produce the design of the structure.

14. The non-transitory machine readable storage medium as defined in claim 9, wherein the instructions cause one or more of the at least one processor circuit to retain SPH particles at or proximate at least one of a boundary or a constraint that are not identified as load carrying.

15. A method comprising:
generating, by executing instructions with at least one processor circuit, a space with a corresponding constraint and a load, the space including smooth particle hydrodynamics (SPH) particles;
identifying, by executing instructions with one or more of the at least one processor circuit, ones of the SPH particles as load carrying to define a keep volume;
moving, by executing instructions with one or more of the at least one processor circuit, ones of the SPH particles that are not identified as load carrying to the keep volume based on the identification; and
generating, by executing instructions with one or more of the at least one processor circuit, a design of a structure based on an arrangement of the SPH particles.

16. The method as defined in claim 15, further including increasing a number of the SPH particles in the keep volume.

17. The method as defined in claim 15, wherein ones of the SPH particles not identified as load carrying are moved toward SPH particles identified to be load carrying.

18. The method as defined in claim 17, wherein the part is produced based on the keep volume.

19. The method as defined in claim 15, further including producing, via an additive production device, a part based on the design of the structure.

20. The method as defined in claim 15, further including retaining, by executing instructions with one or more of the at least one processor circuit, ones of the SPH particles that are not identified as load carrying and positioned at or proximate at least one of a boundary or a constraint.
